(19) United States
(12) Patent Application Publication
(10) Pub. No.: US 2010/0314599 A1
(43) Pub. Date: Dec. 16, 2010

(54) CHALCOGENIDE FILM AND METHOD OF MANUFACTURING SAME

(75) Inventors: Shin Kikuchi, Susono-shi (JP); Yutaka Nishioka, Susono-shi (JP); Isao Kimura, Susono-shi (JP); Takehito Jimbo, Susono-shi (JP); Koukou Suu, Susono-shi (JP)

Correspondence Address: GROSSMAN, TUCKER, PERREAULT & PFLEGER, PLLC, 55 SOUTH COMMERICAL STREET, MANCHESTER, NH, 03101, US

(73) Assignee: ULVAC, INC., Chigasaki-shi (JP)

(21) Appl. No.: 12/742,602

(22) PCT Filed: Nov. 13, 2008
(86) PCT No.: PCT/JP2008/070706

§ 371 Date: Aug. 26, 2010

(30) Foreign Application Priority Data
Nov. 16, 2007 (JP) 2077-297702

(51) Int. Cl. H01L 45/00; H01L 21/02

(52) U.S. Cl. 257/2; 438/381; 257/E21.002; 257/E45.002

(57) ABSTRACT

A chalcogenide film of the invention is formed by a sputtering within a contact hole formed in an insulating layer on a substrate, and is made of a chalcogen compound including a melting-point lowering material that lowers a melting point.

### FIELD OF THE INVENTION

The present invention relates to a chalcogenide film and a method of manufacturing the same, and more particularly, relates to a chalcogenide film which is appropriately used in a recording layer of a high integration memory capable of performing nonvolatile operations such as a phase-change memory, and which does not have defects such as voids or cracks therein, and a method of manufacturing the same.

This application is based on and claims priority from Japanese Patent Application No. 2007-297702, the content of which is incorporated herein by reference.

### BACKGROUND ART

In recent years, there has been an increasing need for handling a large amount of information such as image data in portable devices such as portable telephones or portable information terminals, and there have also been an increase in requests for nonvolatile memories with high speed, low power consumption, high capacity and which are small in size with regard to memory elements mounted in these portable devices.

Specifically, a resistance change-type nonvolatile memory (resistance change-type memory element), which has a changing resistance value depending on a crystalline state in which a chalcogen compound is used, is attracting attention as a high integration memory capable of performing nonvolatile operations (reference to, for example, Japanese Unexamined Patent Application, First Publication No. 2004-348906).

This resistance change-type nonvolatile memory has a simple structure in which a chalcogenide film used as a recording layer is interposed between two electrodes, and is an excellent memory capable of stably maintaining a recording state even at room temperature and also sufficiently holding the memorizing state for a period of time exceeding ten years.

However, in the resistance change-type nonvolatile memory of the prior art, if the element size is simply reduced in size in order to be highly integrated, the gap between adjacent elements becomes extremely small. For example, there has been a problem in that if a predetermined voltage is applied to upper and lower electrodes of a recording layer of one element for the purpose of causing the recording layer to be phase-changed, heat generation from the lower electrode may have an adverse effect on the adjacent elements.

Consequently, there may be considered a structure in which the elements are separated by forming an insulating layer having a low thermal conductivity on the substrate, and forming a small-diameter hole (referred to as a contact hole) in this insulating layer, and then filling this contact hole with the chalcogen compound. In the past, this structure was realized by a method of filling the contact hole with the chalcogen compound by a sputtering.

However, as described above, in the method of filling the contact hole with the chalcogen compound by a sputtering, there has been a problem in that the manufactured chalcogenide film breaks away from the contact hole, and causes a void (air gap) to be generated. In addition, there has been a problem in that, in the characteristics of film-formation by a sputtering, when the depth of the contact hole is equal to or greater than twice the diameter of the contact hole, the contact hole is not entirely filled with the chalcogen compound, and a void remains in the central portion thereof. There has been a problem in that when a void is generated in the chalcogen compound with which the contact hole is filled, the electrical resistance increases which results in conduction defects.

### SUMMARY OF THE INVENTION

The invention was made in view of the above-described situation, and has an object to provide a chalcogenide film which does not have defects such as voids or cracks therein, and a method of manufacturing the same.

The present invention employs the followings in order to achieve the above described object.

(1) A chalcogenide film of the invention is formed by a sputtering within a contact hole formed in an insulating layer on a substrate, and is made of a chalcogen compound including a melting-point lowering material that lowers a melting point.

(2) In the chalcogenide film according to the above (1), it is preferable that the melting-point lowering material contains one, two, or more selected from a group consisting of Si, Al, B, and C.

(3) The chalcogenide film according to the above (1), it is preferable that the melting-point lowering material lowers a melting point of the chalcogen compound to be less than volatile temperature of constituent elements of the chalcogen compound.

(4) The chalcogenide film according to the above (1), it is preferable that the chalcogen compound contains one, two, or more selected from a group consisting of S, Se and Te.

(5) The chalcogenide film according to the above (4), it is preferable that the chalcogen compound contains Te of equal to or greater than 30 at % and equal to or less than 60 at %, Ge of equal to or greater than 10 at % and equal to or less than 70 at %, Sb of equal to or greater than 10 at % and equal to or less than 40 at %, and Se of equal to or greater than 10 at % and equal to or less than 70 at %.

(6) The chalcogenide film according to the above (1), it is preferable that the depth of the contact hole is at least equal to or greater than twice the opening width of the contact hole.

(7) A method of manufacturing a chalcogenide film of the invention is a method for forming the chalcogenide film being made of a chalcogen compound within a contact hole formed in an insulating layer on a substrate, the method including a process of filling the contact hole with the chalcogen compound in which a melting-point lowering material is mixed by use of a sputtering and a reflow, while a temperature of the substrate is maintained to a temperature at which constituent elements of the chalcogen compound do not volatilize.

(8) The method of manufacturing the chalcogenide film according to the above (7), it is preferable that the melting-point lowering material contains one, two, or more selected from a group consisting of Si, Al, B, and C.

(9) The method of manufacturing the chalcogenide film according to the above (7), it is preferable that the temperature of the substrate in the process of filling with the chalcogen compound is set to be equal to or greater than 300° C. and equal to or less than 400° C.

The chalcogenide film of the invention is configured so that the crystal particle diameter of this chalcogenide film is reduced by mixing the melting-point lowering materials in the chalcogen compound and forming a film at a low temperature. The chalcogenide film is formed by filling the contact hole with such a chalcogen compound having fine crystal particles, so that the contact area of the chalcogenide film with the inner wall surface of the contact hole is increased, and adhesion of the contact hole and the chalcogenide film is considerably raised.

Thus, it is possible to positively prevent a defect that the chalcogenide film peels away (breaks away) from the contact hole and the contact hole becomes a void, which results in conduction defects between the lower electrode and the upper electrode.

In addition, according to the method of manufacturing the chalcogenide film of the invention, the melting-point lowering material is mixed in the chalcogen compound and then it is reflowed. Thus, for example, even when a deep hole is formed such that the depth of the contact hole is equal to or greater than twice the opening width, there are no cases where a small space such as a void occurs in the formed chalcogenide film. For this reason, it is possible to prevent electrical resistance of the chalcogenide film from being raised by the void, and to form the chalcogenide film with excellent conductivity.

In addition, the chalcogenide film is formed at a low temperature, so that even when volatile ingredients are included in the chalcogen compound, it is possible to maintain the stoichiometric composition of the chalcogenide film without volatilizing the volatile ingredients.

### BRIEF DESCRIPTION OF THE DRAWINGS

FIG. 1 is a cross-section view illustrating an embodiment of a chalcogenide film according to the invention.

FIG. 2A is a cross-section view illustrating a method of manufacturing the chalcogenide film according to the invention.

FIG. 2B is a cross-section view illustrating the method of manufacturing the chalcogenide film.

FIG. 2C is a cross-section view illustrating the method of manufacturing the chalcogenide film.

### DESCRIPTION OF THE PREFERRED EMBODIMENTS

Hereinafter, the best mode of a chalcogenide film according to the invention will be described on the basis of the drawings.

Here, the embodiment is a specific example for the purpose of better comprehending the effect of the invention, and the invention is not limited thereto, except as otherwise noted.

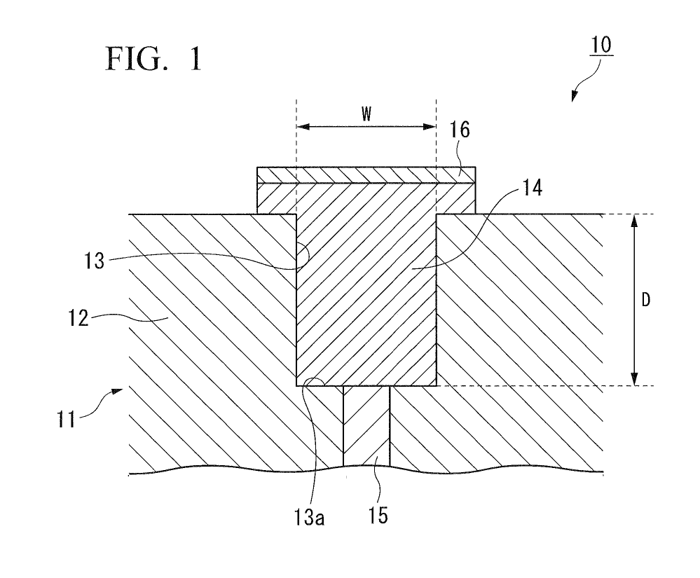

FIG. 1 is a cross-section view illustrating an example of a semiconductor device including a chalcogenide film according to the invention. The semiconductor device 10, appropriately used as a resistance change-type nonvolatile memory, includes a contact hole 13 formed in a insulating film 12 on a substrate 11, and a chalcogenide film 14 formed within the contact hole 13. In addition, a lower electrode 15 of which one end is exposed in a bottom 13a of the contact hole 13 to contact the chalcogenide film 14, and an upper electrode 16 formed on the upper surface of the chalcogenide film 14 are formed in the semiconductor device 10.

The substrate 11 includes, for example, a silicon wafer. The insulating film 12 includes, for example, a silicon oxide film in which the surface of the silicon wafer is oxidized, a silicon nitride and the like. It is preferable that the depth D of the contact hole 13 is at least equal to or greater than twice the opening width W of the contact hole 13.

The chalcogenide film 14 is made of a mixture obtained by mixing a melting-point lowering material in a chalcogen compound to lower the melting point of the chalcogen compound.

The chalcogen compound may contain one, two, or more selected from a group consisting of S, Se and Te. For example, it is preferable that the chalcogen compound contains Te of equal to or greater than 30 at % and equal to or less than 60 at %, Ge of equal to or greater than 10 at % and equal to or less than 70 at %, Sb of equal to or greater than 10 at % and equal to or less than 40 at %, and Se of equal to or greater than 10 at % and equal to or less than 70 at %, and a total percentage of the Te, Ge, Sb, and Se is equal to or less than 100 at %.

The melting-point lowering material may be a material that lowers the melting point of the chalcogen compound as described above so that it is less than a volatile temperature of constituent elements of the chalcogen compound. For example, it may contain one, two, or more selected from a group consisting of Si, Al, B, and C. In particular, it is preferable that the melting-point lowering material is mixed in the chalcogen compound so that the melting point becomes less than 400° C., which is a volatile temperature of Te that is easier to volatilize among the constituent elements of the chalcogen compound.

As described above, it is possible to lower the film-formation temperature at the time of forming the chalcogenide film 14 by using the mixture of the melting-point lowering material in the chalcogen compound as the chalcogenide film 14 formed within the contact hole 13. Therefore, a crystalline structure of the chalcogen compound can be made to be fine.

For example, when the chalcogenide film is formed in a high-temperature environment of 450° C. and the like, the chalcogen compound takes a hexagonal form having a large crystal particle diameter. When the contact hole is filled only with such a hexagonal chalcogen compound, there has been cases where the chalcogenide film peels away (breaks away) from the contact hole, due to the small contact area of particles of the chalcogenide film with the inner wall surface of the contact hole.

However, when the melting-point lowering material is mixed in the chalcogen compound to form the chalcogenide film at a lower temperature than the above-mentioned high-temperature environment, the chalcogen compound becomes a face-centered cubic crystal having a smaller crystal particle diameter than that of the hexagonal crystal. The chalcogenide film 14 is formed by filling the contact hole 13 with such a chalcogen compound having fine crystal particles, so that the contact area of the chalcogenide film 14 with the inner wall surface of the contact hole 13 is increased, and adhesion of the contact hole 13 and the chalcogenide film 14 is considerably raised.

Therefore, the chalcogenide film 14 peels away (breaks away) from the contact hole 13 and the contact hole 13 becomes a void. For this reason, it is possible to positively prevent conduction defects between the lower electrode 15 and the upper electrode 16.

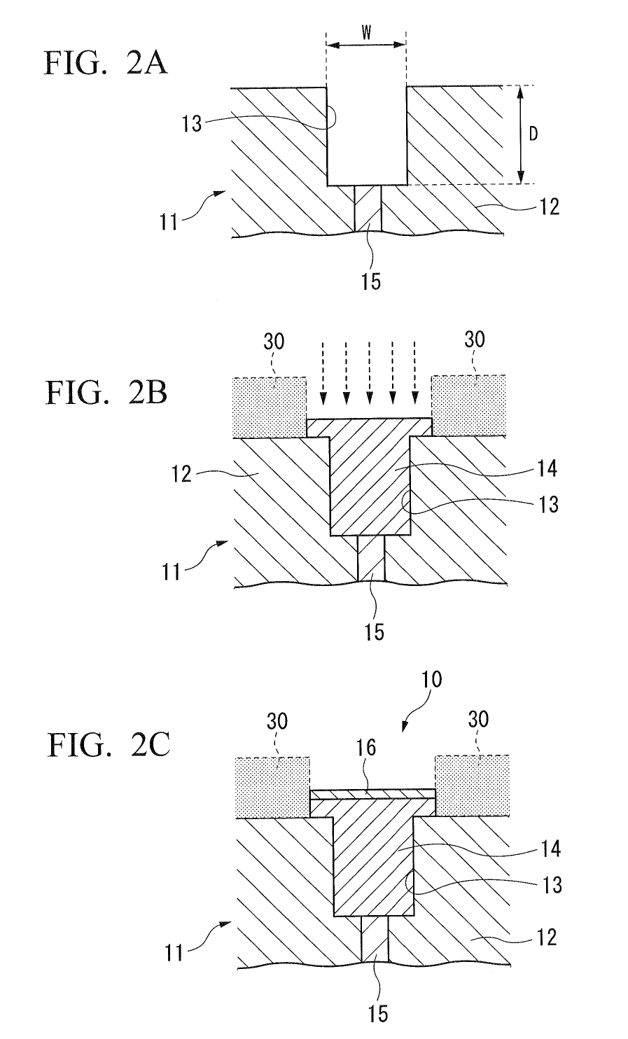

Next, a method of manufacturing the chalcogenide film shown in FIG. 1 will be described below. At the time of manufacturing the chalcogenide film of the configuration shown in FIG. 1, first, as shown in FIG. 2A, the contact hole 13 and the lower electrode 15 are formed in the insulating film 12 of the substrate 11. The contact hole 13 may have the depth D which is equal to or greater than twice, for example, the opening width W.

Next, as shown in FIG. 2B, a resist film 30 is formed in the periphery of the contact hole 13 in a predetermined pattern, and then the chalcogenide film 14 is buried within the contact hole 13. The chalcogen compound in which the melting-point lowering material is mixed is used in the chalcogenide film 14. The melting-point lowering material may contain one, two, or more selected from a group consisting of Si, Al, B, and C.

In a process of filling with this chalcogen compound, the temperature of the substrate 11 is set to be a temperature at which the constituent elements of the chalcogen compound do not volatilize, for example, the temperature of the substrate 11 is set to be equal to or greater than 300° C. and equal to or less than 400° C., so that the chalcogenide film 14 is formed by filling the chalcogen compound in which the melting-point lowering material is mixed within the contact hole 13 by a sputtering and a reflow.

In this way, even when a deep hole is formed such that, for example, the depth D of the contact hole 13 is equal to or greater than twice the opening width W by mixing the melting-point lowering material in the chalcogen compound and then reflowing it, there are no cases where a small space such as a void occurs in the formed chalcogenide film 14. For this reason, it is possible to prevent electrical resistance of the chalcogenide film 14 from being raised by the void, and to form the chalcogenide film 14 with excellent conductivity.

In addition, the chalcogen compound is set to be equal to or less than 400° C., to thereby allow the stoichiometric composition of the chalcogenide film 14 to be maintained when volatile ingredients are included in the chalcogen compound, for example, even when Te is included therein.

As described above, adhesion of the chalcogenide film 14 to the inner wall surface of the contact hole 13 is considerably raised by mixing the melting-point lowering material in the chalcogen compound. Therefore, it is possible to reliably prevent defects such that the chalcogenide film 14 peels away (breaks away) from the contact hole 13 and the contact hole 13 becomes a void, which results in conduction defects between the lower electrode 15, and the upper electrode 16 which is formed in a subsequent process.

After this, as shown in FIG. 2C, when the upper electrode 16 is formed so as to be superimposed on the chalcogenide film 14, and then the resist film 30 is removed, it is possible to manufacture the semiconductor device 10 including the chalcogenide film 14 with excellent electrical characteristics, for example, a resistance change-type nonvolatile memory.

### Example

Hereinafter, a result of verifying the effectiveness of melting-point lowering when the melting-point lowering materials are mixed in the chalcogen compound is exhibited as an example, in order to verify the effectiveness of the invention. At the time of verification, Al, Si, B, and C were each added (at %) stepwise as the melting-point lowering materials to the chalcogen compound composed of Ge 22.2 (at %), Sb 22.2 (at %) and Te 55.6 (at %), and then the degree ΔT (° C.) of the melting-point lowering was investigated. This verification result is shown in Table 1.

TABLE 1

| Additive | | | | |
|---|---|---|---|---|
| Amount (at %) | ΔT (Al) | ΔT (Si) | ΔT (B) | ΔT (C) |
| 2 | 3 | 1 | 0 | 6 |
| 3 | 8 | 6 | 1 | 8 |
| 4 | 21 | 16 | 3 | 16 |
| 5 | 28 | 18 | 6 | 21 |
| 6 | 46 | 25 | 12 | 26 |
| 8 | 50 | 28 | 23 | 21 |
| 10 | 46 | 27 | 22 | 13 |
| 12 | 26 | 26 | 16 | 3 |
| 15 | 10 | 25 | 6 | 0 |

According to the verification result shown in Table 1, it has been found that if the additive amount of Al, Si or B is in the range of 5 at % to 12 at %, there is a significant effect of lowering the melting point of the chalcogen compound. In particular, it has been found that if the additive amount of Al is around 8 at %, the melting point of the chalcogen compound is lowered by approximately 50° C.

The chalcogenide film of the invention is configured so that the crystal particle diameter of this chalcogenide film is reduced by mixing the melting-point lowering materials in the chalcogen compound and forming a film at a low temperature. The chalcogenide film is formed by filling the contact hole with such a chalcogen compound having fine crystal particles, so that the contact area of the chalcogenide film with the inner wall surface of the contact hole is increased, and adhesion of the contact hole and the chalcogenide film is considerably raised.

1. A chalcogenide film which is formed by a sputtering within a contact hole formed in an insulating layer on a substrate, and is made of a chalcogen compound including a melting-point lowering material that lowers a melting point.

2. The chalcogenide film according to claim 1, wherein the melting-point lowering material contains one, two, or more selected from a group consisting of Si, Al, B, and C.

3. The chalcogenide film according to claim 1, wherein the melting-point lowering material lowers a melting point of the chalcogen compound to be less than volatile temperature of constituent elements of the chalcogen compound.

4. The chalcogenide film according to claim 1, wherein the chalcogen compound contains one, two, or more selected from a group consisting of S, Se and Te.

5. The chalcogenide film according to claim 4, wherein the chalcogen compound contains Te of equal to or greater than 30 at % and equal to or less than 60 at %, Ge of equal to or greater than 10 at % and equal to or less than 70 at %, Sb of equal to or greater than 10 at % and equal to or less than 40 at %, and Se of equal to or greater than 10 at % and equal to or less than 70 at %.

6. The chalcogenide film according to claim 1, wherein the depth of the contact hole is at least equal to or greater than twice the opening width of the contact hole.

7. A method of manufacturing a chalcogenide film made of a chalcogen compound within a contact hole formed in an insulating layer on a substrate, the method comprising:
a process of filling the contact hole with the chalcogen compound in which a melting-point lowering material is mixed by a sputtering and a reflow, while a temperature of the substrate is maintained to a temperature at which constituent elements of the chalcogen compound do not volatilize.

8. The method of manufacturing the chalcogenide film according to claim 7, wherein the melting-point lowering material contains one, two, or more selected from a group consisting of Si, Al, B, and C.

9. The method of manufacturing the chalcogenide film according to claim 7, wherein the temperature of the substrate in the process of filling with the chalcogen compound is set to be equal to or greater than 300° C. and equal to or less than 400° C.
